(19) United States
(12) Patent Application Publication
(10) Pub. No.: US 2009/0032100 A1
(43) Pub. Date: Feb. 5, 2009

(54) Position adjustable awning equipped with solar cell plates thereon

(76) Inventor: Eugene Oak, Los Angeles, CA (US)

Correspondence Address: Eugene OAK, 610 S. Van Ness Ave., Los Angeles, CA, 90005, US

(21) Appl. No.: 11/888,817

(22) Filed: Aug. 2, 2007

(51) Int. Cl. H01L 31/045; E04F 10/00

(52) U.S. Cl. 136/259; 160/22

(57) ABSTRACT

An awning, equipped with pluralities of solar cell plates, is provided. The solar cell plates mounted awning can manually be positioned to follow the movement of the sun. The awning is comprised of a square metal frame that has multiple square sectional divisions. Solar cell plates are put on each division. Two wheels that rotate-ably attached on each corner of the upper end of the awning, two rails that are fixed to a part of wall above a window and two telescopic supporting arms connected both sides of the awing and the wall enables the awning to change the position according to movement of the sun. The owner of the house, who installed the awning, can enjoy the sunset outside the window while the awning absorbs the last of the sunlight to provide electricity for the appliances inside the room.

### 1. FIELD OF THE INVENTION

The current application relates to a metal awning structure with solar cell plates installed thereon, especially to an awning that can be adjusted manually according to the movement of the sun.

### 2. BACKGROUND OF THE INVENTION

Since the development of photovoltaic solar cell, many kinds of solar cells and methods of assembling the cells into a module, including the methods of assembling the solar cells for mounting on a house roof, have been introduced. Those methods teach only how to assemble each solar cell and the parts to connect them in a planar shape. According to those illustrations, a lot of heavy metal parts and ceramic insulators are necessary to make whole solar cell modules for mounting them on the roof of a house. The final solar cell module for a house may too heavy for the roof of a house. The heavy weight of the module limits the number of module plates that can be installed on a roof and the magnitude of the power that can be got from them. Moreover, the roof top mounted solar cell plates have a fixed position. This limits the efficiency of utilizing sunlight. However, there are many other places that solar cell plates can be installed. An awning is an instrument that provides shades over a window to block the heat of the sun. It is the purpose of the current application to create an awning that collects the sunlight to generate electricity and maximize the efficiency of the sunlight until sunset.

### DESCRIPTION OF THE PRIOR ART

U.S. Pat. No. 4,238,912 to Mac Donald, U.S. Pat. No. 4,860,509 to Laaly, et al., U.S. Pat. No. 5,232,518 to Nath, et al., U.S. Pat. No. 5,409,549 to Mori, U.S. Pat. No. 5,990,414 to Posnansky, U.S. Pat. No. 6,065,256 to Joko, et al., U.S. Pat. No. 6,606,830 to Nagao, et al., and U.S. Pat. No. 4,636,577 to Peterpaul illustrate a solar panel module for direct mounting on a roof surface. Irrespective of the way of the solar cells are assembled, all methods need many connecting parts comprised of heavy weights.

U.S. Pat. No. 4,204,523 to Rothe illustrates a support for mounting solar energy collectors on the roof of a building, which roof has an opening in the roof sheeting, including a shell that has a generally flat rectangular base and an upstanding edge secured to, and extending about, the periphery of the shell. The frame is configured and dimensional to correspond to the outer surface shape of the roof sheeting and to permit mating receipt thereof in the opening of the sheeting. The mounting support consists of a flat, rectangular shell having a shell edge and a shell bottom. An outer frame surrounds this flat shell, which in its shape is adapted to the shape of the roof sheeting. Thereby, outer frame imitates the form of the often-used roof tiles or any other type of roof sheeting, so that an even sealing off is obtained when inserted into the existing roof sheeting in a manner in which the roofing tiles seal off with each other. The purpose of this solar cell support is to seal off the openings of the roofing.

None of the prior arts illustrate a support frame structure for mounting solar cell plates on an awning of a window to collect the solar energy and shade the window at the same time.

### SUMMARY OF THE INVENTION

Since the development of photovoltaic solar cell, many kinds of solar cells and methods of assembling the cells into a module, including the methods of assembling the solar cells for mounting on a house roof, have been introduced. Those methods teach only how to assemble each solar cell and the parts to connect them in a planar shape. According to those illustrations, a lot of heavy metal parts and ceramic insulators are necessary to make solar cell modules for mounting them on the roof of a house. The final solar cell module for a house may be too heavy for the roof of a house. The heavy weight of the module limits the number of module plates that can be installed on a roof and the magnitude of the power that can be got from them. Moreover, the roof top solar cell plates have a fixed position. This limits the efficiency of utilizing sunlight. However, there are many other places that solar cell plates can be installed. An awning is an instrument that provide over a window to block the heat of the sun. It is the purpose of the current application to provide an awning that collects the sunlight to generate electricity and maximize the efficiency of the sun light until the sun set. The solar cell plates mounted awning according to current application can manually be positioned according to the movement of the sun. The awning is comprised of a square metal frame that has multiple square sectional divisions. Solar cell plates are installed on each dividing. Two wheels that rotate-ably attached on each corner of the upper end of the awning, two rails are fixed to a part of wall above a window and two telescopic supporting arms connected both sides of the awing and the wall enables the awning to change its position according to movement of the sun. The owner of the house, who installed the awning, can enjoy the sunset over the window while the awning absorbs the last of the sunlight to provide electricity for the appliances inside the room.

### BRIEF DESCRIPTION OF THE DRAWINGS

FIG. 1 is a perspective view of a solar cell plate installed awning according to current application.

FIG. 2 is a plan view of a solar cell plate installed awning according to current application.

FIG. 3 is an exploded view of a wall mounted sliding and supporting mechanism of the solar cell plate installed awning according to current application.

FIG. 4 is an exploded view of a rotating connector of the solar cell plate installed awning according to current application.

FIG. 5 is a schematic drawing of a solar cell plate installed awning changing its position along the sun's movement.

### DETAILED DESCRIPTION OF THE PREFERRED EMBODIMENT

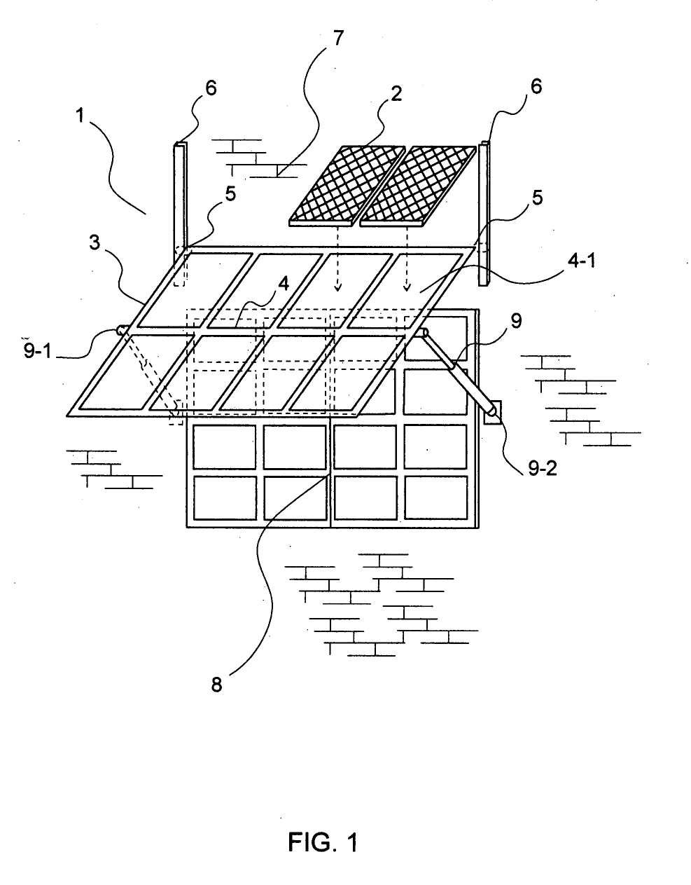

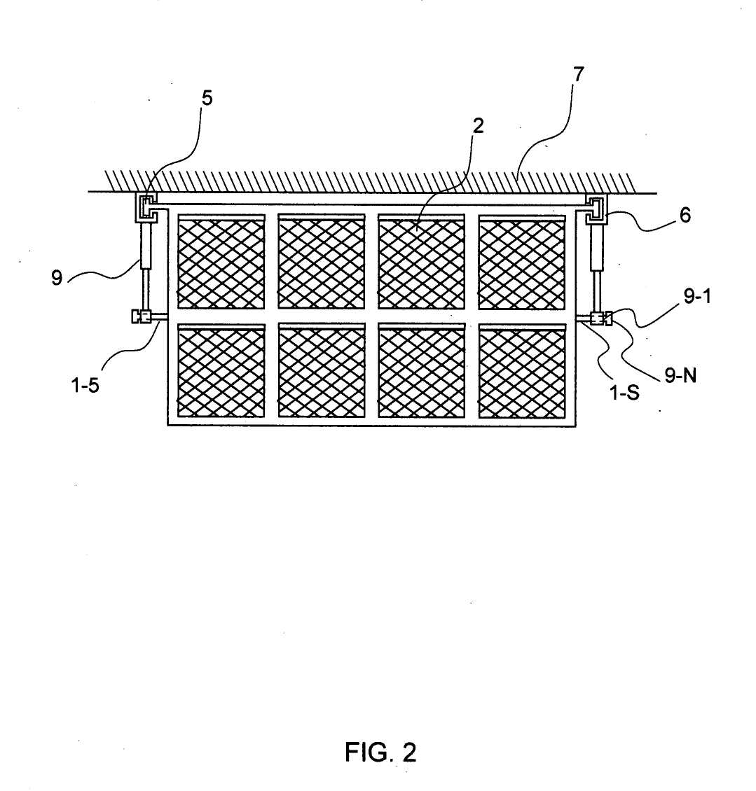

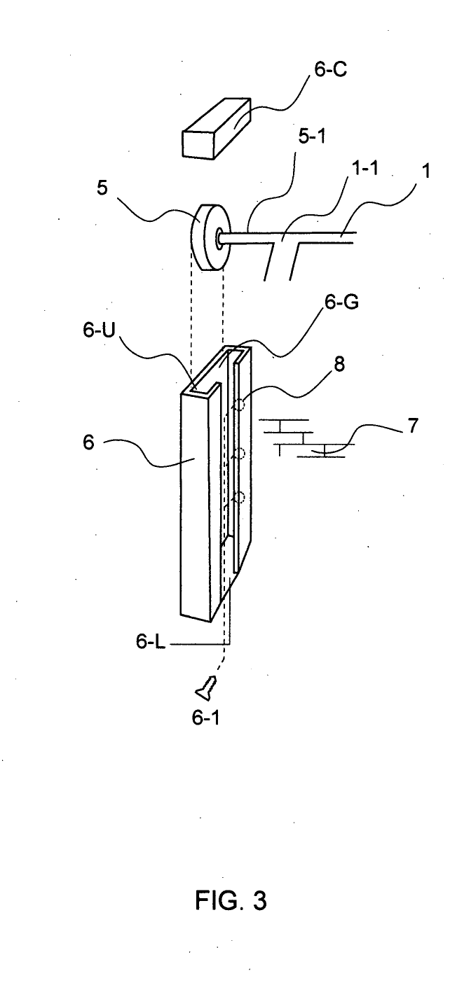

FIG. 1 is a perspective view of a solar cell plate (2) installed awning (1) according to current application. The awning (1) is comprised of a square metal frame (3) that has multiple square sectional divisions (4). FIG. 2 is a plan view of a solar cell plate (2) installed awning (1) according to current application. A wheel (5) is rotate-ably attached on each two corners (1-1) of the upper end of the square awning (1). Each wheel (5) is slide-ably engaged to a rail (6) that is fixed to a part of wall (7) that locates just above a window (8). Two telescopic supporting arms (9) connect both sides of the awing (1) and the wall (7). The upper end (9-1) of each telescopic supporting arm is rotate-ably connected to one side of the awning (1) in the middle and the lower end (9-2) of the supporting arm (9) is rotate-ably fixed to the wall (7) just beside the window (8). Each solar cell plate (2) is mounted on a section (4-1) of the awning (1). Electric wires are connected from the plate (2) to home appliances inside of a room behind the window (7). (Not shown in the drawings). FIG. 3 is an exploded view of a wall mounted sliding and supporting mechanism of the solar cell plate (2) installed awning (1) according to current application. Two sliding and supporting mechanisms are installed on the wall (7) above the window (8). Each sliding and supporting mechanism is comprised of one rail (6) and one wheel (5), which is rotate-ably connected to a shaft (5-1). The shaft is welded to a corner (1-1) of upper end of the square awning (1). Three sides of the rail (6) are closed and part of one side is open. Lower end (6-L) of the rail is closed and upper end (6-U) of the rail (6) is covered by a cap (6-C). The rail (6) is fixed to the wall (7) via three screws (6-1), which penetrate three holes (8) that are developed on a side of the rail (6) that contacts with the wall (7). The wheel (5) is engaged to the rail (6) through the space (6-G) and the cap (6-C) blocks the upper end (6-U) of the rail (6). Then the wheel (5) rotates and moves the upper end of the awning (1) up and down within the trajectory of the rail (6).

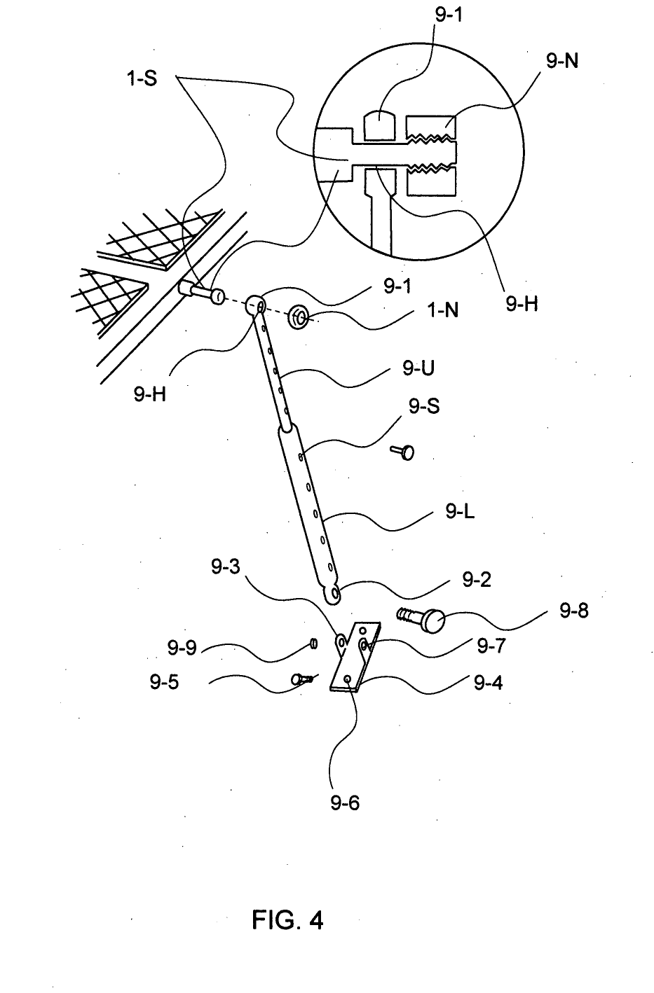

FIG. 4 is an exploded view of a supporting arm (9) of the solar cell plates (2) installed awning (1) according to current application. The rotating arm (9) is comprised of one upper body (9-U) and one lower body (9-L).

Upper end (9-1) of the supporting arm (9), which is a part of the upper body (9-U), has an open hole (9-H), through which a side shaft (1-S) of the awning (1) is engaged. One end of the side shaft (1-S) is welded to a side of the awning (1). The other end of the side shaft (1-S) is screw threaded. A nut (9-N) is engaged to the screw threaded end of the side shaft (1-S).

The lower end (9-2) of the supporting arm (9), which is a part of the lower body (9-L), also has a second open hole (9-H′). The second open hole (9-H′) is inserted between two wings (9-3) of a flange (9-4) that is fixed to the wall (7) via screw bolts (9-5) through holes (9-6). When the lower end (9-2) of the supporting arm (9) is inserted between the two wings, the second open hole (9-H′) and another two holes (9-7) that are developed on the wings (9-3) are aligned. Then a pin (9-8) is inserted through the holes (9-H′), (9-7) and locked by a nut (9-9).

The upper body (9-U) and the lower body (9-L) of the supporting arm (9) are telescopically connected. The upper body (9-U) is slide-ably engaged into the lower body (9-L). Pluralities of small holes (9-S) are developed along the length of the both bodies (9-U), (9-L). Relative position of the both bodies (9-U), (9-L) are adjusted by pulling out and pushing the upper body (9-U) from and into the lower body (9-L). Positions are fixed by a small pin (10).

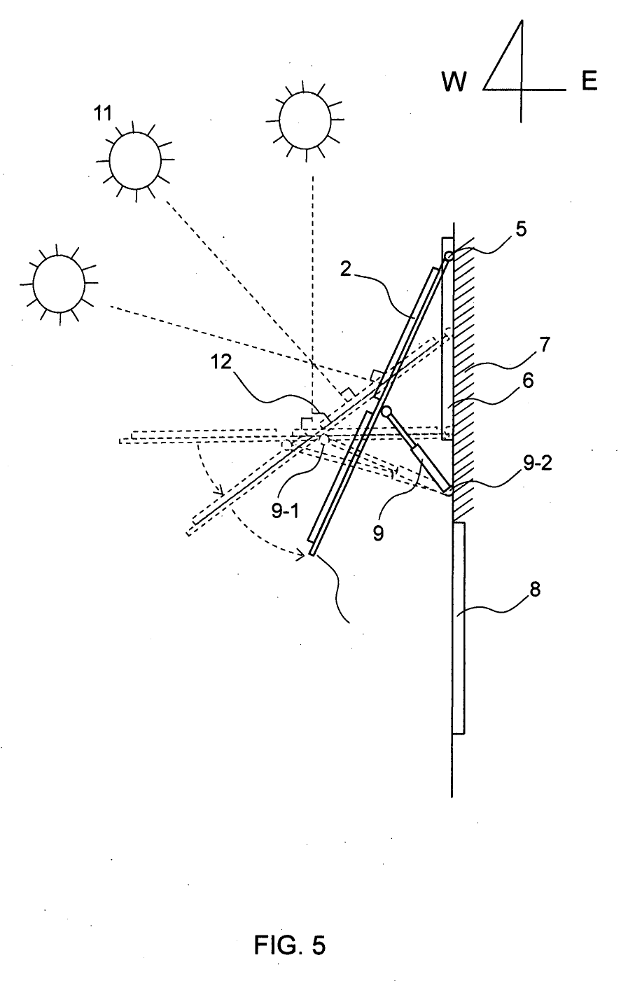

FIG. 5 is a schematic drawing of a solar cell plate installed awning (1) changing it's position along the sun's (11) movement. Most of conventional awnings are fixed to wall over a window. Meanwhile, the solar cell plate (2) installed awning (1) of the current application has a structure that enables changing of it's position along the movement of the Sun (11). If the awning (1) is installed on a wall (7) facing the west, the sun (11) will meet the awning (1) from directly above it at noon. Then, the awning (1) is stretched out and parallel to the ground surface to maximize the contact area with sun light. As the sun (11) goes down, the awning (1) slides inwardly to maintain a rectangle (12) to the sun. Even at evening, the owner of the house can enjoy the sunset while sitting in the room behind the window and turning on a light with the electricity collected from the solar cell plates (2).

What is claimed is:

1. A position adjustable, solar cell plates installed awning that is comprised of:
a square metal frame that has pluralities of square section dividing,
and
two sliding and supporting mechanisms that are installed on the wall above the window, each of which is comprised of;
one rail, which is fixed to a wall via three screws, which penetrate
three holes that are developed on a side of the rail that contacts with the wall,
and
three sides of which are closed and part of one side is open and the lower end of which is closed and upper end of which is covered by a cap,
and
one wheel, which is rotate-ably connected to a shaft that is welded to a corner of upper end of the square awning,
and
two telescopic supporting arms, each of which is comprised of;
one upper body, upper end of which has an open hole, through which a side shaft of the awning, one end of which is welded to a side of the awning and the other end is screw threaded to receive a nut, is engaged
and
one lower body, which slide-ably receives the upper body. and lower end of which has a second open hole that is inserted between two wings of a flange that is fixed to the wall via screw bolts through holes and a pin is inserted through the holes and locked by a nut.
and
one solar cell plate, which is mounted on a section of the awning,
and
electric wires that are connected from the panel to home appliances inside of a room behind the window.

2. A position adjustable, solar cell plates installed awning that is comprised of:
a square metal frame that has pluralities of square section dividing,
and
two sliding and supporting mechanisms that are installed on the wall above the window, each of which is comprised of;
one rail, which is fixed to a wall via three screws, which penetrate
three holes that are developed on a side of the rail that contacts with the wall,
and
three sides of which are closed and part of one side is open and the lower end of which is closed and upper end of which is covered by a cap,
and
one wheel, which is rotate-ably connected to a shaft that is welded to a corner of upper end of the square awning,
and
two telescopic supporting arms, each of which is comprised of;
one upper body, upper end of which has an open hole, through which a side shaft of the awning, one end of which is welded to a side of the awning and the other end is screw threaded to receive a nut, is engaged
and
one lower body, which slide-ably receives the upper body. and lower end of which has a second open hole that is inserted between two wings of a flange that is fixed to the wall via screw bolts through holes and a pin is inserted through the holes and locked by a nut.
and
four solar cell plates, which are mounted on sections of the awning,
and
electric wires that are connected from the panel to home appliances inside of a room behind the window.

3. A postion adjustable, solar cell plates installed awning that is comprised of:
a square metal frame that has pluralities of square section dividing,
and
two sliding and supporting mechanisms that are installed on the wall above the window, each of which is comprised of;
one rail, which is fixed to a wall via three screws, which penetrate
three holes that are developed on a side of the rail that contacts with the wall,
and
three sides of which are closed and part of one side is open and the lower end of which is closed and upper end of which is covered by a cap,
and
one wheel, which is rotate-ably connected to a shaft that is welded to a corner of upper end of the square awning,
and
two telescopic supporting arms, each of which is comprised of;
one upper body, upper end of which has an open hole, through which a side shaft of the awning, one end of which is welded to a side of the awning and the other end is screw threaded to receive a nut, is engaged
and
one lower body, which slide-ably receives the upper body. and lower end of which has a second open hole that is inserted between two wings of a flange that is fixed to the wall via screw bolts through holes and a pin is inserted through the holes and locked by a nut.
and
sixteen solar cell plates, which are mounted on a sections of the awning,
and
electric wires that are connected from the panel to home appliances inside of a room behind the window.
